(19) United States
(12) Patent Application Publication
(10) Pub. No.: US 2019/0088838 A1
(43) Pub. Date: Mar. 21, 2019

(54) MATERIALS FOR LED ENCAPSULATION

(71) Applicants: FRAUNHOHER-GESELLSCHAFT ZUR FOERDERUNG DER ANGEWANDTEN FORSCHUNG E.V., MUENCHEN (DE); OSRAM OPTO SEMICONDUCTORS GMBH, REGENSBURG (DE)

(72) Inventors: GERHARD DOMANN, HOECHBERG (DE); DANIELA COLLIN, WERNECK (DE); CAROLA CRONAUER, WUERZBURG (DE)

(21) Appl. No.: 16/085,370

(22) PCT Filed: Mar. 8, 2017
(86) PCT No.: PCT/EP2017/055479

§ 371 Date: Sep. 14, 2018

(30) Foreign Application Priority Data
Mar. 15, 2016 (DE) 10 2016 104 790.2

(51) Int. Cl. H01L 33/56; H01L 33/48; H01L 33/50; C08G 77/00; C08G 77/20; C08L 83/04; C08K 3/22

(52) U.S. Cl. CPC H01L 33/56; H01L 33/486; H01L 33/501; C08K 3/22; C08G 77/20; C08L 83/04; C08G 77/80

(57) ABSTRACT

A composite material includes a polysiloxane-containing matrix, a dispersant, and dispersed particles. The polysiloxane-containing matrix has a higher refractive index and a higher surface tension than the dispersant in the non-cured state, is produced using two different silanes, and has aromatic groups and organic groups, the latter of which can be bridged together via a bridging agent. Both of the aromatic groups as well as the bridgable organic groups are bonded to a silicon atom via carbon, and the matrix has a bridging agent with two reactive groups for bridging the organically bridgable groups and a catalyst for a bridging reaction such that the organically bridgable groups are reacted with the bridging agent via an addition reaction in the cured state. The dispersant has either groups which can be organically cross-linked thermally and/or under the effect of light or Si—H groups and (ii) aromatic groups.

The present invention relates to a composite which is essentially suitable as an encapsulating material of LEDs and comprises a matrix, particles embedded in the matrix and a dispersing agent, wherein the dispersing agent encloses the particles dispersed in the matrix.

A common problem in LED applications is a too low light extraction efficiency (LEE) of the semiconductor light source. This is partly due to the high refractive index difference between the semiconductor materials of the LED chip and the air surrounding the LED. Due to this difference, a large part of the emitted light is internally reflected by total reflection and not emitted as desired. This reduces the brightness and efficiency of the LED. Another undesirable consequence of the trapped light can be an increased heat generation, which also reduces the coupling-out efficiency, also referred to as conversion efficiency, and can lead to increased degradation of the component (reduced device reliability). Also desirable is the ability to convert the light emitted from the LED, which is often blue or has a cold color, to warmer, longer wavelength light.

In order to reduce the undesirably high refractive index contrast between chip and air, the LED chip is often encapsulated with an encapsulating material. To date, typical encapsulation materials in this case are epoxy-based or silicone-based systems. The advantages of epoxy-based resins are primarily the good adhesion of the material to the housing materials, the high transparency, the relatively high refractive indices and the low costs. This makes them well suited for low energy LEDs. In contrast, while silicones are more expensive and often have a slightly lower refractive index compared to the epoxy systems, they tend to have higher thermal stability which is why they are more frequently used in high-energy LEDs.

Highly refractive silicones achieve refractive indices of about 1.45 up to about 1.54 or 1.55. However, these refractive indices are still significantly lower than the refractive indices of the emitting material of the LED (frequently e.g., GaN, n=2.47 @ 460 nm). For this reason, the encapsulation with these materials alone still results in an unsatisfactory LEE.

Highly refractive, transparent and thermally and light stable materials are required as encapsulation materials also for other technical fields, for example in OLED applications, in photovoltaic applications, in projectors in the display industry and in all optical and opto-electronic systems in which higher temperatures (e.g. >150° C. continuous load) or high optical outputs are used (for example >40 mW/cm² @ 405 nm). Achieving a refractive index of the materials as high as possible is also desirable in these fields.

To date, the increase in the refractive index of the encapsulating material is for example caused by the addition of molecular inorganic components, primarily of (transition) metal compounds, since these often have a high refractive index. In addition to the strategy of increasing the refractive index of the matrix by the incorporation of, for example, titanium (IV) compounds or zirconium (IV) compounds at the molecular level (see, for example, Y. Lai, “Highly transparent thermal stable silicone/titania hybrid with high refractive index for LED encapsulation”, J. Coat. Technol. Res. 2015, 12(6), 1185-1192 or US 2010/025724 A1) and to produce hybrid polymer resins, the refractive index of the encapsulating material can also be increased by the addition of inorganic nanoparticles (e.g., oxides or sulfides). In this case, the size of the nanoparticles has to be clearly below the wavelength of the corresponding light in order to avoid scattering processes as much as possible. The scattering characteristics and the refractive index increase are two complementary potential properties of the nanoparticles in the encapsulation matrix (composite system).

A number of publications describe the development of a highly refractive, chain-like polyorganosiloxane having vinyl groups as cross-linking units, the refractive index of which can be increased by the incorporation of nanoparticles. However, the authors do not describe the production of composite; they also do not describe any difficulties that may arise in the incorporation due to compatibility issues.

In detail, chain-type and end-group-functionalized polyorganosiloxanes having a refractive index of at least 1.50 are described in US 2006/105480 A1. It is not known which refractive indices of the composite can actually be achieved.

US 2009/140284 A1 discloses a highly refractive hardcoat, also based on polysiloxane, the refractive index of which can be further increased by the addition of nanoparticles. The polysiloxanes are cross-linked via typical cross-linking reactions (e.g., methacrylate or epoxy polymerization).

US 2010/025724 A1 describes a highly refractive, three-dimensionally cross-linked polysiloxane as an encapsulation material for LEDs. The syntheses of this material are non-hydrolytic, i.e., without further addition of water for the hydrolysis reaction during the formation of the inorganic network. This is achieved by the use of silanols as essential components. In addition, the stoichiometry, i.e., the possible molar ratio between additionally organically cross-linkable silicon-containing components and aromatic silicon-containing components which are intended to increase the refractive index of the resin, is limited to a quasi-stoichiometric ratio between silanol groups and alkoxysilane groups. The attempt to further increase the refractive index by further increasing the proportion of aromatic constituents must therefore reach its limits based on the route reported in US 2010/025724 A1. The authors in US 2010/025724 A1 further report about the possibility of using nanoparticles to further increase the refractive index.

The challenges, all of which must be considered simultaneously and in their entirety in the manufacture of highly refractive composites for the encapsulation of LEDs, are essentially:

A. Stability of Non-Agglomerated Nanoparticles

A high stability can be achieved by targeted and optimized nanoparticle syntheses and possibly by a subsequent surface functionalization. In the nanoparticle synthesis, hydrothermal or solvothermal synthetic routes (e.g., as described in S. Zhou, “Dispersion Behavior of Zirconia Nanocrystals and Their Surface Functionalization with Vinyl Group-Containing Ligands”, Langmuir 2007, 23, 9178), as well as controlled precipitation reactions (see e.g., T. C. Monson “A simple low-cost synthesis of brookite TiO₂ nanoparticles”, J. Mater. Res. 2013, 28(3), 348) are frequently selected and drying and sintering steps are avoided in order to avoid the risk of irreversible agglomeration. However, some publications also describe synthetic routes in which agglomerate-free nanoparticle dispersions can subsequently be prepared despite drying steps—see, for example, US 2009/140284.

B. Compatibility of Nanoparticles and Matrix

A good compatibility of nanoparticles (NP) and matrix can be achieved by functionalizing the surfaces of the NPs with organic groups. This is particularly successful when the nanoparticles are metal oxide particles. As mentioned before, this functionalization results in a stabilization of the individual particles by steric (or electronic) shielding. In addition, however, functional groups can also be introduced to adjust the polarity of the inorganic oxide particles to that of the organic or hybrid matrix. Moreover, this allows integrating reactive groups which enable a direct covalent bond of the particles to the matrix in the final curing, whereby the compatibility can be further improved. Common examples for this are alkoxysilane-functionalized metal oxide particles such as ZrO₂ nanoparticles for incorporation into silicone resins, acrylate resins or epoxy resins (see, for example, US 2009/140284 A), epoxy- and/or methacrylate-functionalized ZrO₂ nanoparticles for incorporation in epoxy resins such as by P. T. Chung in “ZrO₂/epoxy nanocomposite for LED encapsulation”, Mater. Chem. Phys. 2012, 136, 868 and isopropanol-functionalized TiO₂ particles for use in a silicone resin, see e.g., C.-C. Tuan, “Ultra-High Refractive Index LED Encapsulant”, IEEE Electronic Components & Technology Conference 2014, 447. The surface functionalization is in this case not limited to the use of a single component. Rather, various surface modifiers can be used together. In all the variants presented, it should be noted that a subsequent surface functionalization can contribute massively to the yellowing characteristics.

In the strategy of surface functionalization of the particles to adapt the compatibility, the polarity between particle and matrix has to be adapted for each matrix material. An incorporation often fails when, for specific matrix materials which do not possess the typical functional groups such as methacrylate, acrylate, styryl, epoxy or amino functions or are not cross-linked by typical cross-linking reactions such as radical or cationic polymerization, no suitable functional groups for functionalization can be found.

C. Layer Thicknesses of the Composites (about 500 μm-1 mm) and Problems with Crack Formation

The production of encapsulations for LEDs often requires the processability of the material in the form of thick layers (e.g., in the form of lenses with about 1 mm thickness). If a high number of cross-linking groups is present, an excessively high internal stress can be generated during the curing of the encapsulation material, which is then compensated by crack formation. This is because there are two main reasons for an increased crack formation tendency: On the one hand, this is caused by increased inorganic cross-linking (in particular by tri-instead of dialkoxysilanes) and, on the other hand, reactive groups such as the organic functional groups which are capable of forming networks, for example (meth)acrylates, epoxides, styryl groups and the like, are responsible.

Hence, to be able to produce such thick layers being crack-free, the susceptibility to crack formation of the material must be reduced or optimized. This can be achieved by adapting the number of reactive groups or by incorporating flexible and long-chain molecular building blocks. Examples for this are mentioned in US 2002/195935 A for a granulated, epoxy-based matrix material in which not only thick layers but even exposed encapsulation bodies are presented. US 2006/105480 A describes encapsulating materials which are composed of chain-shaped dimethyl/methylphenyl polysiloxanes and can be cured by means of UV light exposure. In this case, the end-group-functionalized polysiloxane chains allow the processing as a thick layer due to the relatively low proportion of reactive groups compared to the dimensions of the inorganic network. In contrast to chain-like silicones which are built up from dialkoxysilanes as precursors, encapsulation materials based on polysiloxanes can also be synthesized by the use of trialkoxysilanes whose polymeric structure is based less on the formation of chains but much more on three-dimensional inorganic-cross-linked oligomers. By using precursors having reactive organic functional groups, such oligomers whose inorganic network has been obtained by hydrolysis and condensation, carry the reactive groups on the surface, whereby a strong three-dimensional organic cross-linking in the curing step can be achieved. Both the authors of US 2010/025724 A1 and of WO 2012/097836 A1 report on this class of material. For the production of samples with high layer thicknesses of about 1 mm in height, as presented in US 2010/025724 A1, the organic cross-linking and therefore also the number of reactive groups must be controlled in order to avoid crack formation at high layer thicknesses.

On the other hand, a high proportion of aromatic groups, such as phenyl groups, which is highly desirable for obtaining a high refractive index of the system, is favorable in terms of preventing crack formation since they are not amenable to cross-linking and therefore tend to make the matrix material rather soft and flexible.

D. Stability of Highly Refractive Composites (Temperature, UV)

The thermal stability of the encapsulating material simultaneously being exposed to intense light output (especially high-energy blue light, as emitted by most inorganic LED materials) is another requirement. As already mentioned, silicones are significantly more stable than epoxy-based resins. A high yellowing stability is achieved especially when using low-phenyl silicones.

A disadvantage of the use of low-phenyl silicones, however, is that the substitution of the phenyl groups by methyl groups significantly reduces the refractive index of the silicone matrix (the refractive index of methyl silicones is about 1.41, that of phenyl silicones at about 1.53-1.54). Accordingly, significantly more highly refractive particles would have to be incorporated into such a matrix, which is stable in terms of thermal stability and UV irradiation but of low-refractive index, in order to increase the refractive index to the desired value of at least about 1.53-1.54. However, this in turn can limit the processability of the composite since the viscosity of the composite increases very rapidly with increasing particle content and complicates processing, especially since in some applications and process techniques, only solvent-free materials should be processed.

In order to avoid this last-mentioned disadvantage, a matrix with the highest possible refraction would have to be used so that fewer particles are required for the desired refractive index increase. It would of course be particularly beneficial if one could use a matrix whose refractive index is even higher than that of the usual silicones (i.e., above about 1.54 or 1.55), so that the incorporation of relatively small amounts of particles would be sufficient to get the desired properties.

E. Cross-Linking Capability/Curing Behavior

A high proportion of aromatic groups such as phenyl groups is associated with the disadvantage that hardly any organic cross-linking can take place besides the inorganic cross-linking. This is because two to three of the four silicon-bonded radicals must be available to be subjected to a hydrolytic condensation (i.e., for example, be present in the form of alkoxy groups) in order to form an inorganic network, and the phenyl groups are not available for organic cross-linking since they, unlike e.g., styryl groups, have no organically polymerizable radicals. This reduces the possibility of sufficiently curing the material.

It is an object of the invention to provide a highly refractive, yellowing-stable, transparent composite with polysiloxane-based nanoparticles dispersed therein which can be applied to a substrate in the required thicknesses and can be cured without crack formation and which, due to these properties, is suitable for encapsulating LEDs and similar tasks.

This object is achieved by a composite material (uncured) and a composite (cured), comprising a polysiloxane-containing matrix, a dispersing agent and dispersed particles having diameters in the μm to nm range, wherein
(a) the polysiloxane-containing matrix, at least in the uncured state, has a higher refractive index and a higher surface tension than the dispersing agent, is formed using at least two different silanes and comprises aromatic groups and organic groups, the latter being bridgeable with each other via a bridging agent, wherein both the aromatic groups and the organic, bridgeable groups are each bonded via carbon to a silicon atom, wherein the matrix additionally has a bridging agent for bridging the organically bridgeable groups and, if necessary, a catalyst required for the bridging reaction, such that the organically bridgeable groups in the cured state have at least partially reacted via an addition reaction with the bridging agent,
(b) the dispersing agent comprises (i) either groups being organically cross-linkable thermally and/or by exposure to light, or Si—H groups, and (ii) aromatic groups,
   wherein the particles having diameters in the μm to nm range have first been mixed with the dispersing agent and the resulting mixture has been combined with the polysiloxane-containing matrix,
   with the proviso that there are no styryl groups among the aromatic groups of the composite, or that the proportion of styryl groups is less than 5 mol %, preferably less than 1 mol %, based on the total molar amount of aromatic groups in the composite.

Embodiments of the present invention are described in the following items [1] to [25].

[1] A composite material comprising a polysiloxane-containing matrix, a dispersing agent, and dispersed particles having diameters in the μm to nm range, wherein
(a) the polysiloxane-containing matrix, at least in the uncured state, has a higher refractive index and a higher surface tension than the dispersing agent, is formed using at least two different silanes and comprises aromatic groups and organic groups, the latter being bridgeable with each other via a bridging agent, wherein both the aromatic groups and the organic, bridgeable groups are each bonded via carbon to a silicon atom, wherein the matrix additionally has a bridging agent comprising two reactive residues for bridging the organically bridgeable groups and, if necessary, a catalyst required for the bridging reaction, such that the organically bridgeable groups in the cured state have at least partially reacted via an addition reaction with the bridging agent, and
(b) the dispersing agent comprises (i) either groups being organically cross-linkable thermally and/or by exposure to light, or Si—H groups, and (ii) aromatic groups,
   wherein the particles having diameters in the μm to nm range have first been mixed with the dispersing agent and the resulting mixture has been combined with the polysiloxane-containing matrix,
   with the proviso that there are no styryl groups among the aromatic groups of the composite, or that the proportion of styryl groups is less than 5 mol %, preferably less than 1 mol %, based on the total molar amount of aromatic groups in the composite.
      [2] A composite material according to point [1], wherein the polysiloxane-containing matrix comprises at least one first silane selected from silanes having one to three, preferably two, hydrolytically condensable groups and having at least one, preferably two, aromatic groups bound via carbon to the silicon atom of the silane, and at least one second silane selected from silanes having one to three hydrolytically condensable groups and having at least one organic group which is bridgeable via a bridging agent with such an organic group of a second such silane molecule.
      [3] A composite material according to point [2], wherein the first silane is selected from dialkoxydiphenylsilanes, trialkoxyphenylsilanes, derivatives of these silanes in which the phenyl groups are substituted by groups composed of carbon, hydrogen and optionally oxygen, in particular alkyl, and mixtures of the abovementioned silanes, and/or wherein the second silane is selected from trialkoxyvinylsilanes, trialkoxyallylsilanes, trialkoxysilanes carrying a silane methacrylic group, acrylic group or norbornenyl group bonded via carbon to the silicon atom of the silane, trialkoxysilanes carrying an epoxy, thio or amino group bonded via carbon to the silicon atom of the silane, and mixtures of the aforementioned silanes.
      [4] A composite material according to point [3], wherein the second silane is selected from trialkoxyvinylsilanes, trialkoxyallylsilanes, trialkoxysilanes carrying a methacrylic group, acryl group or norbornenyl group bonded via carbon to the silicon atom of the silane, and mixtures of these silanes, and wherein the bridging agent carries at least two reactive radicals selected from Si—H groups and SH groups.
      [5] A composite material according to point [3], wherein the second silane is selected from trialkoxysilanes carrying a thio or amino group bonded via carbon to the silicon atom of the silane, and mixtures of the foregoing silanes, and wherein the bridging agent carries at least two reactive radicals selected from acrylic and methacrylic groups.
      [6] A composite material according to point [3], wherein the second silane is selected from trialkoxysilanes carrying an epoxy group bonded via carbon to the silicon atom of the silane, and wherein the bridging agent carries at least two hydroxy groups as reactive radicals.
      [7] A composite material according to any one of the preceding points, wherein the bridging agent is a silane.
      [8] A composite material according to any one of the preceding points, wherein the bridging agent has at least one aromatic group.
      [9] A composite material according to any one of the preceding points, wherein the bridging agent has a chain length, calculated from a first reactive radical to a second reactive radical without considering the reactive radicals themselves, of at least 6, more preferably at least 8 atoms.
      [10] A composite material according to any one of the preceding points, wherein the molar ratio of silane-bound aromatic groups to organically bridgeable groups in the matrix is in the range of 70 to 95 to 30 to 5.
      [11] A composite material according to any one of the preceding points, wherein the molar ratio of silane-bound organically bridgeable groups and reactive radicals located on the bridging agent lies within the range of 1.1 to 0.9 to 0.9 to 1.1, preferably about 1 to 1.
      [12] A composite material according to any one of the preceding points, wherein the groups of the dispersing agent which are cross-linkable thermally and/or by means of light can undergo a polymerization reaction and are preferably selected from groups which preferably contain activated C═C double bonds.
      [13] A composite material of any one of the preceding points, wherein the dispersing agent is a polysiloxane-containing material composed of at least two hydrolytically condensable silanes, wherein the first silane carries groups which are organically cross-linkable thermally and/or by exposure to light, or Si—H groups, and the second silane carries aromatic groups.
      [14] A composite material according to point [13], wherein the first silane is a (meth)acrylic silane, wherein the (meth)acrylic group is bonded via carbon to the silicon atom of the silane, or a mixture of two or more such (meth)acryl silanes, and the second silane is a phenyl group-containing silane.
      [15] A composite material according to point [13] or [14], wherein the first silane is a trialkoxysilane and the second silane is a dialkoxysilane.
      [16] A composite material according to any one of points [1] to [12], wherein the dispersing agent is a compound which carries groups which can be organically cross-linked either thermally and/or by the exposure to light, or Si—H groups, and (ii) aromatic groups.
      [17] A composite material according to point [16], wherein the dispersing agent is a silane, preferably a disilane.
      [18] A composite material according to point [17], wherein the dispersing agent and the bridging agent of the polysiloxane-containing matrix are identical.
      [19] Composite material according to any one of points [17] and [18], wherein the dispersing agent is or comprises bis[(p-dimethylsilyl)phenyl]ether).
      [20] A composite material according to any one of the preceding points, wherein the particles having diameters in the μm to nm range are surface-modified with groups which are organically cross-linkable thermally or by exposure to light, which are selected to allow their copolymerization with the organically cross-linkable groups of the dispersing agent.
      [21] A composite material according to any one of the preceding points, comprising inorganic particles having diameters in the nm range selected from stoichiometric and substoichiometric oxides, nitrides, oxide nitrides, oxynitride carbides and sulfides.
      [22] A composite material according to any one of points 1 to 20, wherein the particles having diameters in the μm to the nm range are capable of absorbing light radiation of a certain wavelength and of emitting light radiation of a larger wavelength.
      [23] A composite obtained by curing the composite material according to any one of the preceding points.
      [24] A method for producing a composite material according to any one of points [1] to [22], wherein a dispersion of the particles having diameters in the μm to nm range is mixed with the dispersing agent which may be dissolved or dispersed in a solvent and then is combined with the polysiloxane-containing matrix.
      [25] A method of producing a composite according to point [23], wherein a dispersion of the particles having diameters in the μm to nm range is mixed with the dispersing agent optionally dissolved or dispersed in a solvent and is then combined with the polysiloxane-containing matrix, whereupon the resulting composite material is cured by light and/or heat to the composite.

The invention is based on the finding that there are hitherto no transparent, thermally and optically stable composites composed of very high-refractive matrices and suitable particles having diameters in the μm to nm range since matrices, otherwise having the required properties, are incompatible with the respectively desired or required particles having diameters in the μm to nm range in such a way that the composites formed are opaque, as the inventors determined by comparative experiments. In contrast, using the same, highly refractive matrix materials and nanoparticles allows to obtain clear, highly refractive composites, provided a suitable dispersing agent with a slightly lower refractive index is additionally provided. With this additional dispersing agent, a matrix having a very high refractive index and having a relatively high surface tension (a higher polarity) can be selected without the need to use silanes containing styryl groups, which according to the invention should be avoided because of the associated yellowing phenomena. Due to the bridging agent present in the matrix, relatively long-chain organic bridges, which prevent crack formation, are formed during curing. Small impurities of styryls, the proportion of which is so small that yellowing does not occur, are harmless in this case.

The polysiloxane matrix is produced by controlled hydrolysis and condensation reactions from two or more than two hydrolytically condensable silanes, in particular those carrying two and/or three alkoxy groups, as known in the prior art. The number of hydrolytically condensable groups controls the nature of the inorganic network being formed: while silanes having two such groups predominantly form chains and/or rings, the use of silanes having three such groups results in a branched network. Silanes having only one hydrolytically condensable group can serve as chain terminator and therefore, according to the invention, may optionally also be used in smaller amounts.

The matrix has, according to the invention, at least before curing, a higher refractive index and a higher surface tension than the dispersing agent. To this end, at least one of the silanes used for this carries one or more aromatic groups which are usually bound via carbon to the silicon atom. Such groups contribute to a high refractive index of the resin, and it is clear to the person skilled in the art that the number of these groups is responsible for the degree of the refractive index increase. It is therefore preferred when the highest possible proportion of the starting silanes, for example up to about 70% by weight, carries one or preferably two such groups. Particularly suitable aromatic groups are aryl groups, such as unsubstituted or substituted phenyl groups or condensed aromatic groups, such as naphthyl or anthranyl groups. It is also possible to use radicals having two or more phenyl radicals which are isolated from one another, such as bisphenol A derivatives. The substituents of the aromatic rings are preferably alkyl groups or other groups (preferably only) based on carbon, hydrogen and optionally oxygen such as polyoxyalkylene radicals. Due to the known yellowing properties, however, the high refractive index is intended to be effected substantially or completely without the use of styryl groups, so that a substitution of phenyl groups as aromatic groups with vinyl is completely or substantially excluded.

The refractive index can basically be chosen freely; however, in view of the intended applications, it should be as high as possible. Values which are at least higher than the hitherto commercially available values of up to 1.54 or 1.55 are favorable and achievable. Thus, preferably at least prior to curing, the matrix has a refractive index of 1.56 or above, more preferably at least about 1.57 or 1.58. Examples of aromatic silanes of the matrix are mono- or diarylsilanes carrying two hydrolyzable (hydrolytically condensable) groups or OH groups. A small amount of monoarylsilanes can also be added. The use of diarylsilanes is preferred. Examples are diphenylsilanes having two hydrolyzable groups, for example dialkoxydiphenylsilanes such as dimethoxydiphenylsilane.

A second silane, via a bridging agent, carries organic bridging groups which react with this bridging agent during curing of the resin, thereby forming relatively long-chain organic bridges. Typical organically bridgeable groups have C═C double bonds, such as (meth)acrylic groups, allyl groups, norbornene groups or vinyl groups, or also epoxy groups, mercapto groups or amino groups, and are capable of undergoing an addition reaction with the reactive groups of the bridging agent.

Examples of silanes carrying organically bridgeable groups via a bridging agent are vinyl silanes and allyl silanes which can be organically bridged, for example, via Si—H groups or SH groups (by means of a thiol-ene addition). Particularly suitable are vinyl silanes and allyl silanes having three hydrolytically condensable groups such as vinyltrialkoxysilanes or allyltrialkoxysilanes, wherein silanes carrying two vinyl or allyl groups can also be used. The vinyl or allyl group is preferably bound directly to the silicon atom. In a less preferred alternative, these silanes are those which comprise, for example, (meth)acrylic groups which can also be organically bridged with Si—H groups or SH groups. Conversely, when the bridging agent comprises, for example, (meth)acrylic groups, these silanes may be mercaptosilanes (thiosilanes). The expert can easily continue the list of possibilities on the basis of the given conditions.

In the present invention, the term “(meth)acrylic” is intended to mean “methacrylic and/or acrylic”.

The bridging agent is a compound carrying at least two reactive radicals which can be added to the organically bridgeable groups mentioned, or a combination of two or more of these compounds. The reactive radicals can be, for example, mercapto groups which can bind to (meth)acrylate or norbornene groups by thiol-ene addition, reactive hydrogen groups which can bind to an allyl or vinyl group, or hydroxy groups which can bind to an epoxy group. If the silane contains mercapto groups or amino groups as organically bridgeable groups, activated non-aromatic C═C double bond-containing radicals such as (meth)acrylic radicals can also be preferably used as reactive radicals of the bridging agent. It is also favorable when the bridging agent also carries aromatic groups in order to avoid a “dilution” of these groups in the matrix by the addition of the bridging agent. If the bridging agent has more than two, for example three, reactive radicals, it can have a cross-linking effect.

Since the present invention allows to dispense with the styryl groups, which are known to contribute to the yellowing, a significantly increased stability of the high-refractive polycondensate results, as compared to conventional high-refractive phenylsilicones.

A silane compound may, but need not, be also used as a bridging agent. When this compound should carry reactive hydrogen groups, these may be Si—H groups. Alternatively, it may be, for example, a thiosilane whose thio group is bonded to a silyl radical which is bonded to the silicon via carbon. Particularly suitable is a compound which carries two silicon atoms having active groups, for example, Si—H groups. These two silicon atoms can be linked together via a diphenylene ether bridge. A concrete example is bis[(p-dimethylsilyl)phenyl]ether).

When replacing styryl groups by aromatic derivatives without organic cross-linkable groups such as the vinyl group, the cross-linkability of the material is first reduced, as stated above, which can adversely affect the curing behavior. This is compensated for by bridging a part of the organic radicals bonded to silicon via carbon via an addition reaction with a bridging agent which has at least two reactive groups. The reactive groups of the bridging agent increase the total number of reactive groups. It is advantageous, for example, to add a bridging agent having two reactive groups, for example Si—H groups, in such an amount to the silane that has bridgeable groups, e.g., vinyl groups, that the ratio of the reactive groups of the bridging agent to the number of bridgeable groups on the silane is stoichiometric. This doubles the number of bridgeable groups. It is particularly advantageous when the atomic chain has as many links as possible between at least two of the reactive radicals of the bridging agent, because the bridging then results in a relatively wide-meshed network; however, it should be noted that long aliphatic chains reduce the refractive index. However, this does not apply to more extended aromatic chains whose aromatic components need not necessarily be conjugated. The chain (calculated without the reactive radicals) between the two reactive radicals should, based on the above considerations, preferably have at least 6, more preferably at least 8 chain members, wherein for any ring which may be present, such as phenyl rings, the shortest distance between the two binding sites of the rings is calculated. For p-phenyl structures, for example, these are 4 (carbon) atoms.

Due to the normally aqueous synthesis of the polycondensate, a free choice regarding the stoichiometry of the different silane precursors is generally possible. The ratio of aromatic group-containing silanes to organic bridgeable groups is basically not critical, as long as a sufficient number of aromatic groups is present so that the desired, high refractive index is achieved. Of course, the highest possible proportion of aromatic groups is favorable. In view of the fact that the refractive index should be as high as possible, while ensuring that a sufficient proportion of organically bridgeable groups for curing by to resin is present, it is advantageous to use the aromatic-containing silane in a molar proportion, based on the sum of aromatic groups and organically bridgeable groups, of up to about 80%; however this proportion can increase under certain circumstances even up to about 95%, preferably up to about 90% (for example, when 30 mol % vinyltrialkoxysilane and 70 mol % dialkoxydiphenylsilane are used, the proportion is about 82 mol %). On the other hand, by using a sufficient amount of organically cross-linkable groups, a mechanically stable matrix is obtained, which is why the proportion of these groups should not be too low. It is favorable when their proportion, based on the sum of the aromatic groups and the organically cross-linkable groups, is not less than 5 mol %, preferably not less than 8 mol % (for example, the proportion is about 8 mol % when using 15 mol % vinyltrialkoxysilane and 85 mol % dialkoxydiphenylsilane). More preferably, however, this proportion is slightly higher, for example at about 20, possibly even up to about 30 mol %.

The bridging agent for the organically cross-linkable groups is advantageously selected in a stoichiometric proportion, i.e., in such an amount such that each bridgeable group can react stoichiometrically with a reactive radical of the cross-linking agent. If the polycondensate was prepared from the at least two different silane precursors using an insufficient amount of aromatic group-containing silanes in order to be able to adjust the refractive index of the matrix sufficiently high (and higher than that of the dispersing agent), the cross-linking agent should contain as high a proportion as possible of aromatic groups in order to provide the matrix with the desired high refractive index.

Via additional precursors, it is in principle possible to integrate further functional groups into the polycondensate and/or to have an effect on the inorganic network formation. The aim of influencing the inorganic network formation and of the selection of additional functional groups is, besides the high refractive index of the resin and the thermal stability, also the processability of the encapsulation material with layer thicknesses of up to 1 mm or even more. Examples of such precursors are silanes having four hydrolytically condensable groups which increase the proportion of inorganic cross-linking and thus make the material more mechanically stable and not subject to shrinkage. It is also possible to use silanes having organically polymerizable radicals, for example radicals which can be poly-added which can not react with the bridging agent but can be cross-linked by heat or light in a later polyreaction, for example, silanes containing (meth)acrylate groups, because this may result in a further refractive index increase; however, this measure should be used with caution because it goes hand in hand with an increased risk of shrinkage. Furthermore, silanes which contain one (or more) longer chain alkyl group(s) can be used, which reduces the brittleness of the later composite and increases the flexibility of the network. The resin matrix is preferably produced by subjecting the two different silanes which carry organically cross-linkable groups or aromatic groups via a bridging agent, together to a hydrolytic condensation reaction. To this end, the silanes are mixed, which is usually possible without the addition of a solvent since the starting components are usually liquid. The mixture is then subjected to hydrolysis and condensation which can be effected, for example, with a substoichiometric to stoichiometric amount of water, based on the hydrolytically condensable radicals present, and optionally a catalyst, for example, acid such as hydrochloric acid. The compounds released in the condensation, such as ethanol or methanol, are then removed together with the excess water and preferably the catalyst, which can be effected by extraction with an extraction agent and/or by stripping (distilling) of volatile components. The resulting inorganic condensate is a storable resin. If it is to be processed with the other components of the composite according to the invention, the cross-linking agent and, if necessary, a corresponding catalyst are added.

The dispersing agent is required for incorporating the particles into the high-refractive matrix. According to the invention, the dispersing agent should also be as highly refractive as possible, without contributing to a yellowing of the layer. For this reason, like the matrix, it should carry aromatic groups which may be selected from the same group of aromatics, for example arylene, as mentioned above for the matrix. Preferably, aryl-containing silanes are used as the source for these. The dispersing agent should additionally be organically cross-linkable or it should allow formation of an organic bridge.

The type of the organic cross-linkability can be selected with a view to the particles to be used, though either a cross-linkability of the cross-linkable groups chosen for the dispersing agent with one another and/or a cross-linkability with a component of the matrix can also be envisaged.

If the cross-linkable groups are chosen with a view to the particles to be used, it may be advantageous to use cross-linkable groups which are susceptible to organic polymerization thermally and/or by exposure to light. If, for example, particles are used whose surface is also covered by organically polymerizable groups, these particles can be copolymerized via said groups with the corresponding component of the dispersing agent and can thereby be covalently incorporated into the composite. A cross-linkability of the organically cross-linkable groups selected for the dispersing agent and/or a cross-linkability with a component of the matrix is possible, for example, when groups are used which can be subjected to a polymerization thermally using light (“addition polymerization”). Examples of these are groups which preferably contain activated C═C double bonds, such as acrylic or methacrylic groups or norbornenyl groups. A cross-linkability with a component of the matrix is possible, for example, if the dispersing agent has Si—H groups. In these cases, a cross-linking with the matrix and possibly also with the nanoparticles is possible when the matrix and possibly also the particles have groups containing C═C double bonds on their surface. The cross-linkable groups are preferably provided via silanes, which in a first embodiment of the invention are subjected to a hydrolytic condensation reaction. For the binding of these groups to the silicon atoms, essentially the same applies as stated above for the matrix resin.

In one exemplary embodiment, a (meth)acrylate-based polycondensate, i.e., a polycondensate having groups which can be organically polymerized thermally and/or by exposure to light, is selected as the dispersing agent for a vinyl-functionalized resin to be used for the matrix. These groups can be introduced via silanes since these groups contain radicals bound via carbon to the silicon.

The aromatic groups of the dispersing agent can also be provided via silanes which, in this variant, can be subjected to hydrolytic co-condensation with the silanes having organically cross-linkable groups. These silanes may, for example, have two or three hydrolytically condensable groups and one or two aryl groups, the latter also being bonded to the silicon via carbon.

In one alternative, the dispersing agent is chosen to allow an organic bridging. In this case, no inorganic condensate is formed. This dispersing agent is referred to as a molecular dispersing agent, as opposed to the polycondensed dispersing agent described above. Like the bridging agent of the matrix resin, it carries two reactive groups and may be selected from the same group of compounds as the bridging agent. Optionally, it may be identical to the bridging agent.

In one embodiment of such a dispersing agent for a likewise vinyl-functionalized matrix resin, one may choose a silane compound containing at least two Si—H groups which is first contacted with the nanoparticles and subsequently with the resin and results in the cross-linking and curing of the composite. This silane compound may optionally itself have aromatic groups, for example aryl groups, or it may be combined with other aromatic-containing silanes.

The dispersing agent in this case has a polarity adapted to mediate between the optionally functionalized nanoparticles and the high refractive index matrix.

Basically, the amount of use thereof is not limited; however, it should be sufficient to allow encapsulating the particles having diameters in the μm to nm range. The term “encapsulation” in this case is intended to mean that the polarity is thereby optimized to the extent that a compatibility and miscibility is given. This does not mean, however, that complete ancapsulation in the sense of comprehensive coverage of the surface of the nanoparticles and steric shielding is mandatory, although this will frequently be achieved. The proportion of dispersing agent, based on the sum of matrix and dispersing agent, can therefore vary between 1 and 99% by weight; normally about 10 to 50% by weight, based on the stated sum of matrix and dispersing agent, is used.

Surprisingly, it has been found that the dispersibility of the particles can be increased by the addition of the dispersing agent, even if the surface tension-related polarities of the different polycondensates of the matrix differ only slightly from each other.

The particles of the invention in the dispersed state have diameters in the μm to nm range. In case they serve to increase in refractive index, this diameter is below the wavelength of the light for the passage of which the composite according to the invention is provided, i.e. between about 400 nm to about 800 nm on average. These particles are also called nanoparticles. If the particles are intended for the conversion of light, as explained in more detail below, the diameter can also be above 800 nm and, for example, possibly also reach about 50 μm.

As refractive index increasing nanoparticles, it is for example possible to use commercially available nanoparticles which are functionalized on the surface preferably with a wide variety of groups or which are prepared according to typical synthesis instructions (e.g., according to S. Zhou, supra) and are optionally also functionalized by different surface reactions. The nanoparticles preferably consist of metal oxides or metal nitrides, for example those of zirconium or titanium. They are preferably present in dispersion. The functionalization may, but need not, be located in one or more organically polymerizable groups that can be applied via silanization. The presence of organically cross-linkable or polymerizable groups which can copolymerize with the corresponding organically cross-linkable groups of the dispersing agent is preferred.

Instead of or in addition to particles which increase the refractive index, particles can be used with which the color of an LED can be specifically changed. In these cases, the composite is not or not only used to encapsulate the LED; rather, the layer containing or consisting of the composite (only or in addition) serves as a so-called conversion layer. Conversion layers contain particles or nanoscale substances that absorb the short-wave, high-energy light emitted by the LED which is perceived as “cold” light, and re-emit the energy absorbed in the form of light of longer wavelengths (e.g., yellow).

The light emitted by the LED (which, in the case of, for example, InGaN or GaN as semiconducting material, is mostly blue or even emitting in the UV range) is sent in this technology through the conversion layer which I supported either directly on the LED chip or has a certain distance thereto (the latter is called “remote phosphor”). In both cases, the layer can simultaneously serve as an encapsulation layer. Since a part of the light emitted by the LED passes the conversion layer without absorption, but mostly scattered, the light rays emitted from the conversion layer then overall result in a white light impression. Semiconductor materials are often used as converter substances. When they are particulate matter (phosphors), they often have a diameter in the μm scale, e.g., 1-50 μm, which are used as a powder. An example (which is not to be considered as limiting) is cerium-doped yttrium aluminum garnet Y₃Al₅O₁₂:Ce, a material from the group having the general form A₃B₅X₁₂:M, which contains further phosphors. Alternatively, as mentioned, nanoscale conversion materials (nanoparticles) can be used which are also referred to as quantum dots. A typical representative is CdSe, which, however, due to the toxicity of cadmium, has recently been competing with Cd-free materials such as InP or InP/ZnS as well as other sulfides such as PbS and ZnS. These converter materials generally have the object of improving or changing the performance, efficiency and color value of the LED. An essential challenge in this case is the adequate stabilization and distribution of the converter materials in a respective matrix. Above all, an agglomeration and accumulation of the phosphors on the bottom of the applied layer must be avoided before the layer has hardened, in order to avoid shifts in the color dots and to enable the uniformity of the color values.

The composite according to the invention is produced by mixing the dispersing agent and the nanoparticles together, wherein both components are used dissolved in a suitable solvent if necessary. The solvent is then removed, for example by distillation and optionally subsequent application of heat and reduced pressure. Subsequently, the resin of the matrix and the dispersing agent blended with the nanoparticles are mixed. If no catalyst for the bridging reaction was incorporated into the matrix resin yet, but is required, this catalyst is added to the mixture. Likewise, an initiator or catalyst for the polymerization reaction of the polymerizable groups of the dispersing agent is added. The resulting mixture is then cured, which is preferably carried out by heat.

According to the invention, therefore, the use of a dispersing agent is proposed as a supplementary component for a translucent, clear, yellowing-resistant and highly refractive composite. With the invention, composites can be obtained which, after curing, have refractive indices of more than 1.6, preferably of more than 1.65. Thus, it is possible to provide higher-refractive and more stable encapsulation systems and/or conversion layers, in particular for LEDs that increase the LEE, even in the absence of styryl compounds.

### EMBODIMENTS

### 1. Particle Systems

The particles used in the examples had a particle diameter (DLS, volume weighted, including functionalization shell) of about 5 to 8.3 nm. They had a core of ZrO₂ with an acrylate and/or methacrylate-modified surface. Their refractive index (including functionalization shell) was in all cases about 1.8. They were used in the form of a 50% suspension in PGMEA (1-methoxy-2-propyl acetate).

### 2. Resin Synthesis (Matrix Resin)

0.15 mol (22.9 g) of vinyltrimethoxysilane and 0.30 mol (75.9 g) of dimethoxydiphenylsilane are placed in a 500 ml three-necked flask with a stirrer bar and stirred. Subsequently, 0.495 mol (8.91 g) 0.5 N hydrochloric acid solution are added dropwise and stirred for ten minutes. Subsequently, the mixture reacts for 24 h at 80° C. in an oil bath. After completion of the reaction, the reaction mixture is incorporated into 270 ml of ethyl acetate and washed to pH neutrality with 115 ml of water. The resin thus obtained is then purified via a hydrophobic filter and the remaining volatile constituents are removed by distillation. The refractive index of the resin thus obtained is 1.5795 (598 nm, 20° C., Abbe refractometer). For curing of the resin, 0.589 g (bis[(p-dimethylsilyl)phenyl]ether), 1% by weight of a 1.8×10⁻³% by weight solution of platinum(0)-1,3-divinyl-1,1,3,3-tetramethyldisiloxane in xylene based on the resin are mixed with 2.0 g of resin. The surface tension of the resin is 37.8 mN/m. The refractive index of the cured layer is 1.5970 (635 nm, prism coupler).

The molar mass of the Si—H compound of 286.52 g/mol gives, at 0.589 g, a quantity of substance of 2.06 mmol. The molar ratio of vinyl component to diphenyl component is 1:2, resulting in a mass concentration of 16.6% by weight for the hydrolyzed and condensed vinyl component in the resin. That means 2.0 g of resin contains 0.332 g of the hydrolyzed and condensed vinyl component. With a molar mass of 79 g/mol (methoxy groups are deducted because of the hydrolysis, the 0 atoms are half counted, as they contribute to the inorganic cross-linking), this results in a quantity of substance of 4.2 mmol vinyl groups in the resin. Since the Si—H containing compound is bifunctional, the ratio of Si—H groups and vinyl groups is stoichiometric.

### 3. Synthesis of a Polycondensed Dispersing Agent Having Methacrylate Groups

0.20 mol (49.9 g) of 3-methacryloxypropyltrimethoxysilane and 0.40 mol (101 g) of dimethoxydiphenylsilane are placed in a 500 ml three-necked flask with a stirrer bar and stirred. Subsequently, 0.66 mol (11.9 g) 0.5 N hydrochloric acid solution are added dropwise and stirred for ten minutes. Subsequently, the mixture reacts for 24 h at 80° C. in the oil bath. After completion of the reaction, the reaction mixture is incorporated into 360 ml of ethyl acetate and washed to pH neutrality with 150 ml of water. The resin thus obtained is subsequently purified via a hydrophobic filter and the remaining volatile constituents are removed by distillation. The refractive index of the resin thus obtained is 1.5681 (598 nm, 20° C.) and the surface tension is 35.6 mN/m. Despite the relatively small difference in the surface tension, the dispersing agent causes the used ZrO₂ nanoparticles to allow their optimal dispersion and to produce an agglomeration-free, transparent layer. The refractive index of the cured layer is 1.583 (635 nm, prism coupler).

### 4. Production of Composites by Means of a Polycondensed Dispersing Agent

In a first step, 2.08 g of dispersing agent (see Example 3) are dissolved in 50 ml of 1-methoxy-2-propyl acetate in a 250 ml round bottom flask. 8.91 g of a 50% by weight solution of surface-functionalized ZrO₂ nanoparticles in 1-methoxy-2-propyl acetate are added to this solution. The mixture is treated for 30 minutes in an ultrasonic bath. Subsequently, the solvent is removed by distillation. Remaining residues of the volatile constituents are removed in a vacuum oven at 60° C. to thus obtain the dispersed nanoparticle mixture. In a second step, for the matrix, 4.78 g of a resin of vinyltrimethoxysilane and dimethoxydiphenylsilane are mixed in a molar ratio of 1:2 as described above in Example 2 with 1.41 g (bis[(p-dimethylsilyl)phenyl]ether) and stirred for two hours.

Subsequently, the two mixtures are combined so that the ratio of dispersing agent to resin is 2.1:1, and the composite mixture is stirred for four hours at room temperature. Subsequently, 0.1% by weight of dicumyl peroxide based on the dispersing agent and 1% by weight of a 1.8×10⁻³% by weight solution of platinum(0)-1,3-divinyl-1,1,3,3-tetramethyldisiloxane in xylene based on the resin are added.

The subsequent curing of thin layers of this composite can be carried out by a three-stage oven treatment at e.g., first 100° C. for two hours, 150° C. for one hour and finally 180° C. for another hour. The refractive index of the ZrO₂-containing composite with the aid of a polycondensed dispersing agent is 1.650 (635 nm—prism coupler measurement on cured samples).

### 5. Production of Composites Using a Molecular Dispersing Agent Having Si—H Groups

In a first step, 0.573 g (bis[(p-dimethylsilyl)phenyl]ether are placed in a 50 ml round bottom flask. Subsequently, 2.87 g of a 50% by weight solution of surface-functionalized ZrO₂ nanoparticles in 1-methoxy-2-propyl acetate are added dropwise. The mixture is stirred for 15 minutes at room temperature, followed by the addition of 0.0218 g of a 1.8×10⁻³% by weight solution of platinum(0)-1,3-divinyl-1,1,3,3-tetramethyldisiloxane in xylene. The reaction mixture is first stirred for 24 h at 60° C. and then for 4 h at 80° C. in an oil bath to obtain the dispersibility in the resin. Subsequently, 1.438 g of the resin (see Example 2) are added to the reaction mixture and the resulting transparent composite is stirred for a further hour at room temperature.

The subsequent curing of thin layers of this composite is carried out at 100° C. for 7 h in an oven. The refractive index of the ZrO₂-containing composite layers thus obtained by means of a molecular dispersing agent with SiH groups is 1.635 (635 nm—prism coupler measurement of the cured layer). The refractive index of layers of the pure resin (see Example 2) is 1.597 (635 nm, prism coupler) in this measurement method.

6. Comparative Example without Dispersing Agent

First, 2.18 g of a 50% by weight solution of surface-functionalized ZrO₂ nanoparticles in 1-methoxy-2-propyl acetate are placed in a 50 ml round bottom flask. 0.439 g (bis [(p-dimethylsilyl)phenyl]ether), 0.015 g of a 1.8×10⁻³% by weight solution of platinum(0)-1,3-divinyl-1,1,3,3-tetramethyldisiloxane in xylene and 1.099 g of the resin of vinyltrimethoxysilane and dimethoxydiphenylsilane are added successively in a molar ratio of 1:2 as described above in Example 2. The mixture is stirred for a total of 24 h at room temperature. The subsequent curing of thin layers of this composite is carried out at 100° C. for 7 h in the oven. The resulting layer is not transparent but rather white and cloudy. Scanning electronic investigations of the composite cross-section show an increased agglomeration of the ZrO₂ nanoparticles. The size of the resulting agglomerates is between about 400 nm and several 10 microns and is thus in the range of scattering particles.

Overview of the properties (layer quality, refractive index) of the resulting composites (particle content: 12% by volume)

| | | | With |
|---|---|---|---|
| Composites of ZrO₂ | | With molecular | polycondensed |
| and | Without | dispersing agent | dispersing agent |
| Base resin (from | dispersing | having SiH | (methacrylate |
| Example 1) | agent | groups | groups) |
| Layer quality | x | ✓ | ✓ |
| | cloudy | Clear, | Clear, transparent |
| | | transparent | |
| Refractive index of | Not | 1.635 | 1.650 |
| the composite layers | definable | | |
| (prism coupler, | | | |
| 635 nm) | | | |

### 7. Comparative Example for the Synthesis of a Polycondensed Dispersing Agent Having Styryl Groups

0.25 mol (57.02 g) of styryl trimethoxysilane and 0.50 mol (126 g) of dimethoxydiphenylsilane are placed in a 500 ml three-necked flask equipped with a stirrer bar and stirred. Subsequently, 0.825 mol (14.9 g) 0.5 N hydrochloric acid solution are added dropwise and stirred for ten minutes. Subsequently, the mixture reacts for 24 h at 80° C. in an oil bath. After completion of the reaction, the reaction mixture is incorporated into 450 ml of ethyl acetate and washed to pH neutrality with 200 ml of water. The resin thus obtained is subsequently purified via a hydrophobic filter and the remaining volatile constituents are removed by distillation. The refractive index of the resin thus obtained is 1.5983 (598 nm, 20° C., Abbe refractometer) and that of the cured layer 1.6013 (635 nm, prism coupler).

Comparison of the thermal properties of styryl-containing or methacryl-containing polycondensed dispersing agent

The difference in thermal stability of the two dispersing agents is already evident from the different transmission values (see table), when the pure dispersing agents are cured using 1% by weight of the initiator dicumyl peroxide as a 1 mm thick layer at 150° C. for 2 h and finally at 180° C. for 1 h in an oven. The increased absorption in the styryl-containing material due to yellowing components from the starting material styryltrimethoxysilane is clearly visible. This effect is even more pronounced in case of a subsequent thermal aging (72 h, 150° C.). For this reason, styryl-containing dispersing agents are not suitable for low-yellowing, high-refraction LED encapsulating materials.

| | | Reduction |
|---|---|---|
| Material | | transmission at 400 nm |
| Polycondensed | Cured (150° C., 2 h + | −9% |
| dispersing agent | 180° C./0.5 h) | |
| (methacrylate- | + thermal aging | |
| containing) | (150° C./72 h) | |
| Polycondensed | Cured (150° C./2 h + | −62% |
| dispersing agent | 180° C./0.5 h) | |
| (styryl-containing) | + thermal aging | |
| | (150° C./72 h) | |

8. Comparative Example for the Production of a Composite with a Pure Dispersing Agent as a Matrix

First, 3.38 g of the dispersing agent (according to Example 3) are introduced and diluted with 84.7 g of 1-methoxy-2-propyl acetate. The mixture is homogenized for 15 min in an ultrasonic bath. Subsequently, 11.9 g of a 50% by weight solution of surface-functionalized ZrO₂ nanoparticles in 1-methoxy-2-propyl acetate are added dropwise and the mixture is treated with ultrasound for further 30 min. The solvent 1-methoxy-2-2propylacetat is removed from the reaction mixture by distillation down to a residual solvent content of about 4% by weight and a thermal radical initiator dicumyl peroxide is weighed-in with a content of 0.3 percent by weight based on the dispersing agent. The refractive index of the composite mixture thus prepared was 1.6034 (598 nm, 20° C., Abbe refractometer).

The subsequent curing of thin layers of this composite is carried out initially at 150° C. for 2 h and finally at 180° C. for 1 h in an oven. The necessary high curing temperature of the pure matrix in this case led to yellowing of the particles or, more precisely, of the organic groups on the surface of the particles and thus to marked yellowing of the cured composite thus obtained, which is why the use of the dispersing agent as a matrix for the composite production is not suitable here.

1-15. (canceled)

16. A composite material, comprising:
a polysiloxane-containing matrix;
a dispersing agent;
particles having diameters in a μm to nm range;
said polysiloxane-containing matrix having, at least in an uncured state, a higher refractive index and a higher surface tension than said dispersing agent, and is composed using at least two different silanes, and containing aromatic groups and organic bridgeable groups, said organic bridgeable groups being bridgeable with each other via a bridging agent, wherein both said aromatic groups and said organic bridgeable groups are each bonded via carbon to a silicon atom;
said bridging agent of said polysiloxane-containing matrix containing at least two reactive radicals for bridging said organically bridgeable groups and, a catalyst required for a bridging reaction, such that said organic bridgeable groups in a cured state are at least partially reacted via an addition reaction with said bridging agent;
said dispersing agent containing (i-1) either groups which are organically cross-linkable thermally and/or by exposure to light, or (i-2) Si—H groups, and (ii) aromatic groups; and
said particles having said diameters in the μm to nm range have first been mixed with said dispersing agent and a resulting mixture being been combined with said polysiloxane-containing matrix, with a proviso that there are no styryl groups among said aromatic groups of the composite material, or that a proportion of the styryl groups is less than 5 mol %, based on a total amount of said aromatic groups in the composite material.

17. The composite material according to claim 16, wherein said two different silanes include at least one first silane selected from said silanes having one to three hydrolytically condensable groups and carrying at least one aromatic group bound via the carbon to the silicon atom of a silane, and has at least one second silane selected from said silanes having one to three hydrolytically condensable groups and having at least one organic group which is bridgeable via said bridging agent with such an organic group of a second such silane molecule.

18. The composite material according to claim 17, wherein:
said first silane is selected from the group consisting of dialkoxydiphenylsilanes, trialkoxyphenylsilanes, derivatives of said silanes in which phenyl groups are substituted by groups composed of carbon, hydrogen and oxygen, and mixtures of said aforementioned silanes; and/or
said second silane is selected from the group consisting of trialkoxyvinylsilanes, trialkoxyallylsilanes, trialkoxysilanes carrying a methacrylic group, an acrylic group or a norbornenyl group bonded via the carbon to the silicon atom of the silane, trialkoxysilanes carrying an epoxy group, thio group or amino group bonded via the carbon to the silicon atom of the silane, and mixtures of said aforementioned silanes.

19. The composite material according to claim 18, wherein said second silane is selected from the group consisting of said trialkoxyvinylsilanes, said trialkoxyallylsilanes, said trialkoxysilanes carrying said methacryl group, said acryl group or said norbornenyl group bonded via said carbon to said silicon atom of said silane, and mixtures of said silanes, and wherein said bridging agent at least carries two reactive radicals selected from Si—H groups and SH groups.

20. The composite material according to claim 18, wherein said second silane is selected from said trialkoxysilanes carrying a thio group or amino group bonded via the carbon to said silicon atom of said silane, and mixtures of said aforementioned silanes, and wherein the bridging agent carries at least two reactive radicals which are selected from acryl groups and methacryl groups.

21. The composite material according to claim 18, wherein said second silane is selected from said trialkoxysilanes carrying an epoxy group bonded via said carbon to said silicon atom of said silane, and wherein the bridging agent carries at least two hydroxy groups as reactive radicals.

22. The composite material according to claim 16, wherein said bridging agent is a silane.

23. The composite material according to claim 16, wherein said bridging agent contains at least one aromatic group.

24. The composite material according to claim 16, wherein said bridging agent has a chain length, calculated from a first reactive radical to a second reactive radical without considering the reactive radicals themselves, of at least 6 atoms.

25. The composite material according to claim 16, wherein a molar ratio of silane-bound organically bridgeable groups and of reactive radicals on said bridging agent lies in a range from 1.1 to 0.9 to 0.9 to 1.1.

26. The composite material according to claim 16, wherein groups of said dispersing agent which are cross-linkable thermally and/or by means of light can undergo a polymerization reaction and are selected from groups which contain activated C═C double bonds.

27. The composite material according to claim 16, wherein said dispersing agent is a polysiloxane-containing material composed of at least two hydrolytically condensable silanes, wherein a first silane carries either groups organically cross-linkable thermally and/or by exposure to light, or Si—H groups, and a second silane carries aromatic groups.

28. A composite, comprising:
the composite material according to claim 16 being cured.

29. A method for producing a composite material, which comprises the steps of:
providing a dispersing agent containing (i-1) either groups which are organically cross-linkable thermally and/or by exposure to light, or (i-2) Si—H groups, and (ii) aromatic groups;
providing a polysiloxane-containing matrix having, at least in an uncured state, a higher refractive index and a higher surface tension than the dispersing agent, and is composed using at least two different silanes, and containing aromatic groups and organic bridgeable groups, said organic bridgeable groups being bridgeable with each other via a bridging agent, wherein both the aromatic groups and said organic bridgeable groups are each bonded via carbon to a silicon atom, said polysiloxane-containing matrix additionally containing a bridging agent with at least two reactive radicals for bridging said organically bridgeable groups and, a catalyst required for a bridging reaction, such that said organic bridgeable groups in a cured state are at least partially reacted via an addition reaction with the bridging agent;
providing particles having diameters in a μm to nm range; and
mixing a dispersion of the particles having diameters in the μm to nm range with the dispersing agent and then combined with the polysiloxane-containing matrix, with a proviso that there are no styryl groups among the aromatic groups of the composite material, or that a proportion of the styryl groups is less than 5 mol %, based on a total amount of the aromatic groups in the composite material.

30. A method for producing a composite, which comprises the steps of:
providing a dispersing agent containing (i-1) either groups which are organically cross-linkable thermally and/or by exposure to light, or (i-2) Si—H groups, and (ii) aromatic groups;
providing a polysiloxane-containing matrix having, at least in an uncured state, a higher refractive index and a higher surface tension than the dispersing agent, and is composed using at least two different silanes, and containing aromatic groups and organic bridgeable groups, the organic bridgeable groups being bridgeable with each other via a bridging agent, wherein both the aromatic groups and the organic, bridgeable groups are each bonded via carbon to a silicon atom, the polysiloxane-containing matrix additionally containing a bridging agent with at least two reactive radicals for bridging the organically bridgeable groups and, a catalyst required for a bridging reaction, such that the organic bridgeable groups in a cured state are at least partially reacted via an addition reaction with the bridging agent;
providing particles having diameters in a μm to nm range;
mixing a dispersion of the particles having diameters in the μm to nm range with the dispersing agent and then combined with the polysiloxane-containing matrix resulting in a composite material, with a proviso that there are no styryl groups among the aromatic groups of the composite material, or that a proportion of the styryl groups is less than 5 mol %, based on a total amount of the aromatic groups in the composite material; and
curing the composite material by light and/or heat to obtain the composite.
